(19) United States
(12) Patent Application Publication
(10) Pub. No.: US 2005/0088823 A1
(43) Pub. Date: Apr. 28, 2005

(54) VARIABLE DENSITY GRAPHITE FOAM HEAT SINK

(76) Inventors: Ashok N. Kabadi, Portland, OR (US); Gary W. Brady, Aloha, OR (US); Frank R. Deweese, McMinnville, OR (US); Harry L. Hampton III, Aloha, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/692,443

(22) Filed: Oct. 22, 2003

(51) Int. Cl. H05K 7/20

(52) U.S. Cl. 361/704; 361/708

(57) ABSTRACT

A heat sink is disclosed for directing heat away from an electronic component dissipating heat. The heat sink includes a thermally conductive base formed of a variable density graphite foam article. This graphite foam heat sink having variable foam densities provides for higher cooling capacity than existing heat sinks.

### BACKGROUND INFORMATION

Microprocessors and other electronic circuit components are becoming more and more powerful with increasing capabilities, resulting in increasing amounts of heat generated from these components. Packaged units and integrated circuit die sizes of these components are decreasing or remaining the same, which increases the amount of heat energy given off by the components for a given unit of surface area. Furthermore, as computer related equipment becomes faster, more and more components are being placed inside equipment, which is also decreasing in size, resulting in additional heat generation in a smaller volume of space. Increased temperatures can potentially damage the components of the equipment, or reduce the lifetime of the individual components and the equipment. Therefore, large amounts of heat produced by many such integrated circuits must be dissipated, and therefore must be accounted for in designing the integrated circuit.

For the reasons stated above, and for other reasons stated below which will become apparent to those skilled in the art upon reading and understanding the present specification, there is a need for better thermal conductivity from existing heat sinks.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the inventions.

FIG. 1 is a perspective view of a graphite foam heat sink assembly.

FIG. 2 is a cross sectional view taken along line 4-4 of FIG. 1 illustrating a copper spreader.

FIG. 3 is a cross sectional view of the graphite foam heat sink illustrating a copper sleeve.

FIG. 4 is a perspective view of a graphite foam heat sink with an evaporative chamber having a copper chamber assembly.

FIG. 5A is a schematic of the top and bottom chambers of the evaporative chamber.

FIG. 5B is a cross sectional view of FIG. 5A.

### DETAILED DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well know devices, circuits, and methods are omitted so as not to obscure the description of the present invention with unnecessary detail.

Graphite foam is a new material developed by scientists at the Oak-Ridge National Lab. The thermal conductivity of 90% graphite foam has been shown to be approximately equal to that of copper, but its density is ⅙^{th} that of copper, making it much lighter than copper for the same volume and thus having better heat dissipation. However, the graphite foam heat sink, at a much lower weight than the best HVM heat sink (copper core, aluminum fins), has a higher cooling capacity in the same volume. A heat sink assembly can be formed of graphite foam material using two different densities for high-powered component heat sinks. Thereby producing very high performance heat sinks that can be made using the graphite foam material.

It should be noted that for purposes of illustration, 25% and 90% graphite foam densities are illustrated. However, it should be known that any density may be applied. Moreover, the current illustration contains two types of densities, 25% and 90%, however any amount of densities may be used to achieved a similar result.

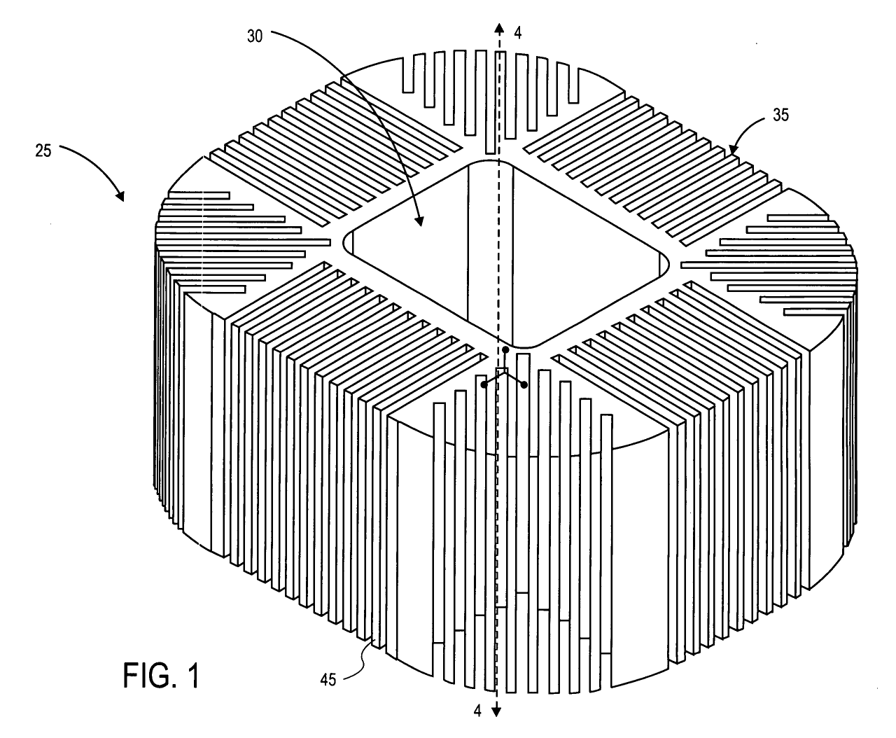

FIG. 1 illustrates a schematic view of a graphite foam heat sink assembly 25. The graphite foam heat sink assembly 25 may consists of a center core or base 30 that is thermally conductive. The center core 30 may be made of 90% dense graphite foam. The thermal conductivity of 90% dense graphite foam is 380 Watts/Meter*Kelvin which is higher than that of copper which is 350 W/M*K. The density of 90% dense graphite foam core 30 is 1.4 gms/cc, which is ⅙^{th} that of copper and thus making the graphite foam heat sink assembly 25 much lighter than copper for the same volume.

The nominal dimensions of 90% dense graphite foam core 30 may be 1.331″×1.091″ and 1.43″ high with corner radii of 0.151″. The outer shell 35 may be made of 25% dense graphite foam, which has a thermal conductivity of 200 W/M*k. The outer shell 35 may consists of a center hole that has an interference fit with the 90% dense graphite core 30. The nominal dimensions of the center hole may be 1.330×1.090×1.437. It should be noted that these dimensions can vary based on the variable density of the graphite foam.

The outer shell 35 may have fins 45 cut into it. The fins 45 can be 0.040″ wide with a 0.040″ gap. The fins 45 are cut radially along the four corners of the graphite foam heat sink assembly 25. The graphite foam heat sink assembly 25 having the dimensions described above in FIG. 1, would provide 78 full length fins 45. However, it should be noted that it is possible to have numerous numbers of fins. For example, if the fins 45 are made 0.050″ wide and 0.050″ gap, this would give the graphite foam heat sink assembly 25 a total number of 60 fins 45.

By using graphite foam for both the center core 30 and fins 45, the heat sink assembly 25 has a much higher cooling capacity than existing materials such as copper and aluminum. This is because 90% graphite dense foam and 25% graphite dense foam have higher thermal conductivities than copper and aluminum, respectively. The thermal conductivity of the 90% dense graphite core 30 has a thermal conductivity of 380 W/M*K and the thermal conductivity of the 25% graphite foam core 35 is 200 W/M*K. Moreover, since the density of the graphite foam material is much lower than both copper and aluminum, the estimated weight of the graphite foam heat sink assembly 25 is 100 grams compared with 270 grams of the existing heat sinks. In addition, unlike a solid graphite block, which is unidirectional, the present graphite foam conducts heats in all directions due to its ligament structure. The thermal conductivity across the ligaments of the graphite foam is measured to be 1700 W/M*K. The following Table 1 compares the thermal conductivities and densities of the copper, aluminum and the 25% and 90% dense graphite foam.

| | | Thermal |
|---|---|---|
| Material | Density | Conductivity |
| Copper | 8.8 | 350 |
| Aluminum | 2.8 | 180 |
| 25% dense graphite | .65 | 200 |
| 90% dense graphite | 1.4 | 380 |

As shown in Table 1, for the same volume of existing heat sinks, the graphite foam heat sink assembly 25 has a higher cooling capacity (lower theta degrees C/Watt from Heatsink to air) at a much lower weight. Existing heat sinks can cool power densities up to 50 watts/Cm sq. Whereas, the graphite foam heat sink assembly 25 has cooling capacity of power densities in excess of 60 watts/ Cm sq. Furthermore, for the same heat sink performance as current heat sinks, the graphite foam heat sink assembly 25 is smaller, allowing the use of more space on the mother-board for placing decoupling caps closer to electronic components, such as, microprocessors. As the power dissipation of microprocessors exceeds 85 watts, the current materials such as copper and aluminum will be unable to meet the cooling requirements using conventional air-cooled technology. The graphite foam heat sink assembly enables microprocessors to cool beyond 100 watts of power dissipation using air-cooled technology.

Existing heat sinks have a copper core that is pressed into the outer shell of aluminum with radial fins. Copper has a thermal conductivity of 350 Watts/M*K and aluminum 180 Watts/M*K. The weight of heat sinks using copper and aluminum are 270 grams, which is at the upper limit to pass system-level shock and vibration test. To improve the thermal interface between the graphite foam heat sink assembly 25 and an electronic component, such as a microprocessor, a thin flat copper heat spreader 50 may be added to the bottom of the graphite foam heat sink core 30. This results in the graphite foam heat sink assembly 25 having a much higher cooling capacity than existing technology.

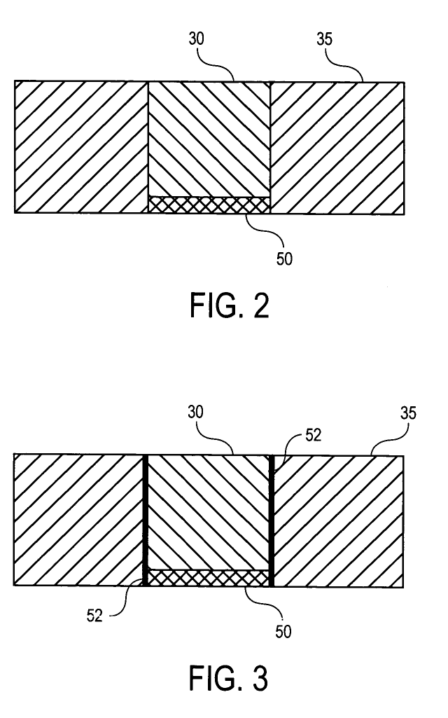

As illustrated in FIG. 2, a thin 0.125″ thick copper spreader 50 is soldered to the 90% graphite foam core 30 of the graphite foam heat sink assembly 25. However, it is possible to have a copper spreader of a different thickness based on the application. The thermal resistance between the copper and graphite is kept minimum by soldering the two surfaces using solder either 50/50 (Sn/Pb) or 63/37 (Sn/Pb). The copper spreader 50 makes contact with the heat spreader of an electronic component. The copper spreader's 50 mechanical tolerances on the flatness and surface finish can be held much tighter than that of machined graphite. Since the flatness and surface finish are critical in the area of contact to the spreader on the electronic component, an optimum copper spreader 50, C10100, is illustrated, however, various copper spreaders can be used. Moreover, copper has a high thermal conductivity (350 Watts/M*k) and does not add much to the overall weight because the thickness is kept to its minimum of 0.125″.

Since the density of the graphite foam material is much lower than both copper and aluminum, the estimated weight of the graphite foam heat sink assembly 25 with a thin copper spreader 50 is 170 grams compared with 270 grams for existing heat sinks. Thus, for the same volume of current heat sinks, the graphite foam heat sink assembly 25 using a copper heat spreader 50 has at least 125% the cooling capacity (lower theta—degrees C/Watt from Heatsink to air) than current technology with ⅓rd its weight. Alternatively, for the same heat sink performance as existing heat sinks, the graphite foam heat sink assembly 25 is much smaller, allowing the use of more space on the mother-board for placing decoupling caps closer to the electronic component. As the power dissipation of existing heat sinks go beyond 85 watts, the current materials such as copper and aluminum are unable to cool the microprocessors using conventional air-cooled technology. The graphite foam heat sink assembly 25 with copper spreader 50 will allow electronic components to cool beyond 100 watts of power dissipation using air-cooled technology.

FIG. 3 illustrates a copper sleeve 52. To further improve the thermal interface between the graphite foam heat sink assembly 25 and an electronic component, such as a microprocessor, a thin flat copper sleeve 52 may be added. The graphite foam core 30, made of 90% dense graphite foam, may be pressed into the copper sleeve 52. Once pressed, the copper sleeve 52 may now press with the outer shell 35, which is 25% graphite foam.

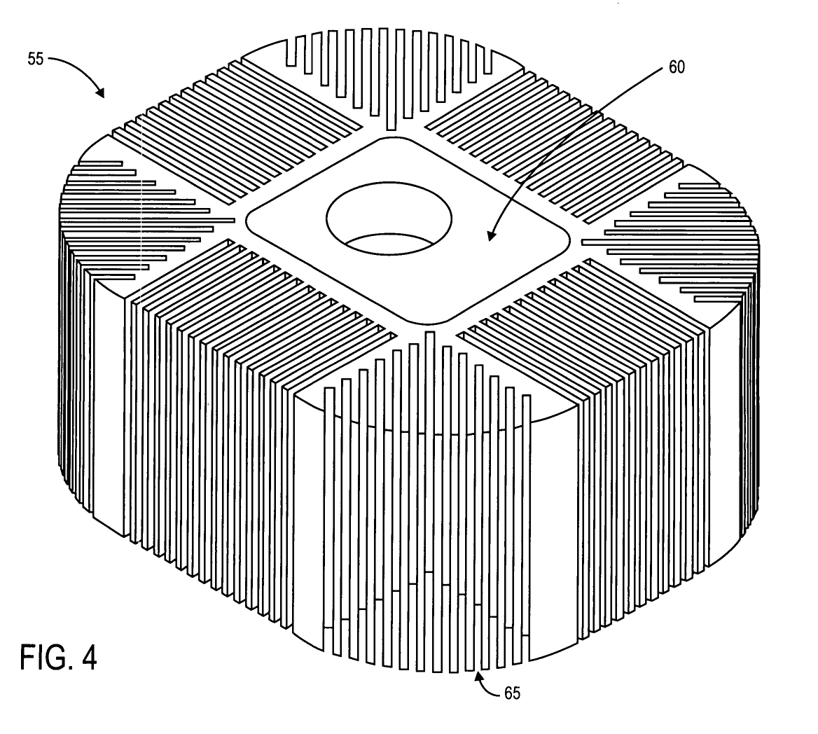

FIG. 4 illustrates a perspective view of a graphite foam heat sink with an evaporative chamber 55. The graphite foam heat sink with an evaporative chamber 55 may consists of a center copper chamber assembly 60, which is pressed into the outer shell of 90% dense graphite foam with radial fins 65. The 90% dense graphite foam has a thermal conductivity of 380 Watts/Meter*Kelvin, which is much higher than that of aluminum which is typically used for the fins.

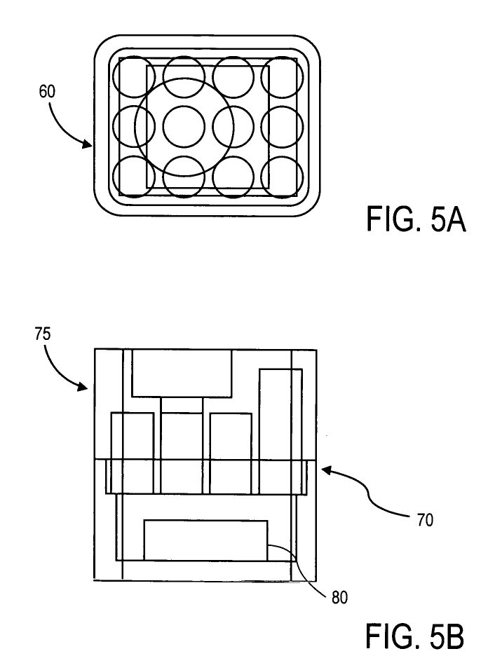

The copper chamber assembly 60 may consist of bottom 70 and top 75 copper chambers as illustrated in FIGS. 5A and 5B. A 25% dense graphite foam 80 may be soldered to the inside of the base of the bottom chamber 70 using low temperature solder (50/50, Sn/Pb or 63/37, Sn/Pb). Typically a copper mesh may be used inside of the chamber 60. However, if the copper mesh is replaced with a 25% dense graphite foam 80 as a wicking material to transfer heat from the electronic component, the thermal performance is significantly better.

The 25% dense graphite foam 80 may be used as a water wicking material inside the copper chamber assembly 60. The water is used as fluid and is placed inside the chamber assembly 60 to transfer the heat from the bottom of the chamber 70 to the top of the chamber 75. The 25% dense graphite foam 80 acts as a wick for the water and spreads the heat across the bottom chamber 70. The top 75 and bottom 70 chambers are soldered using low temperature solder like Indalloy # 1==50% Indium, 50% Sn that is liquidus at 125 degrees C.

The top evaporative chamber 75 has several blind tapped holes to provide a large surface area for the vapors to cool and condense into water drops and drain back into the bottom chamber 70. The top chamber 75 also has a ¼-20 tapped through hole that is used to draw the vacuum and seal the top 75 and bottom 70 chambers. The water gets heated in a vacuum and turns into vapors that goes into the tapped holes in the top chamber 75 and gets condensed and returns back to the bottom chamber 70. Due to a very high specific thermal conductivity of the 25% graphite foam 80 and its wicking properties, the heat is almost instantly spread across the bottom 70 and top 75 chamber making the copper chamber assembly 60 a highly efficient heat spreader. This heat is dissipated into the air by the shell that is comprised of 90% dense graphite foam fins 65 that can be 0.040″ wide and 0.040″ gap. Alternatively, a different fin width and spacing can be used. The graphite foam heat sink with an evaporative chamber 55 with 25% graphite foam 80 as wicking material and 90% dense foam as fins 65 will have a cooling capacity in excess of 200 watts/cm sq. and thus will be able to cool microprocessors dissipating power beyond 150 watts.

Although the foregoing examples describe a particular utility of using graphite foam in heat sinks, some embodiments of the invention may also find more general utility in graphite foam in other electronic or mechanical systems.

The foregoing and other aspects of the invention are achieved individually and in combination. The invention should not be construed as requiring two or more of the such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

1. A heat sink comprising:
a thermally conductive base comprised of a variable density graphite foam article having a first and second opposed surfaces; and
an electronic component thermally coupled to the second surface of the thermally conductive base.

2. The heat sink of claim 1, further comprising a plurality of fin structures extending upwardly from the thermally conductive base.

3. The heat sink of claim 1, wherein the thermally conductive base density is comprised of about 90% graphite foam.

4. The heat sink of claim 2, wherein the plurality of fin structures is comprised of about 25% graphite foam.

5. The heat sink of claim 2 wherein the plurality of fin structures are formed at the first surface of the thermally conductive base.

6. The heat sink of claim 1 further comprising a copper article spread on the second surface of the thermally conductive base.

7. The heat sink of claim 6, wherein the copper article contacts the electronic component.

8. The heat sink of claim 6, wherein the copper article is about 0.125″ thick.

9. The heat sink of claim 1, further comprising a copper sleeve spread between the first and second surfaces.

10. The heat sink of claim 3, wherein the nominal dimensions of the 90% dense graphite foam base is about 1.331″×1.091″ and 1.43″ high with corner radii of 0.151″.

11. A heat sink comprising a variable density graphite foam article shaped so as to provide a first and second surfaces, wherein arranging the second surface of the graphite foam article in operative connection with an electronic component causes dissipation of heat from the electronic component through the second surface of the graphite foam article.

12. The heat sink of claim 11, further comprising a copper article spread over the second surface of the graphite foam article.

13. The heat sink of claim 11 wherein the first surface of the graphite foam article is comprised of about 25% graphite foam.

14. The heat sink of claim 11 wherein the second surface of the graphite foam article is comprised of about 90% graphite foam.

15. The heat sink of claim 11 further comprising a copper sleeve spread between the first and second surfaces.

16. An evaporative chamber comprising:
a copper chamber assembly having first and second opposed surfaces;
a electronic component thermally conductive with the second surface of the copper chamber assembly.

17. The evaporative chamber of claim 16, wherein interior of the second surface base is comprised of 25% graphite foam.

18. The evaporative chamber of claim 17, wherein the 25% graphite foam is a liquid conduit for heat collection from the electronic component.

19. The evaporative chamber of claim 16, wherein the first surface contains apertures for heat dissipation.

20. The evaporative chamber of claim 16, wherein the outer surface of the copper chamber assembly is formed of about 90% graphite foam.

21. The evaporative chamber of claim 16, wherein the first surface is comprised of a plurality of fins.
